(19) United States
(12) Patent Application Publication
(10) Pub. No.: US 2016/0005778 A1
(43) Pub. Date: Jan. 7, 2016

(54) Semiconductor Package and Method for Manufacturing the Same

(71) Applicant: Samsung Electronics Co., Ltd., Suwon-si (KR)

(72) Inventor: Hyunsu Jun, Seongnam-si (KR)

(21) Appl. No.: 14/730,348

(22) Filed: Jun. 4, 2015

(30) Foreign Application Priority Data
Jul. 7, 2014 (KR) 10-2014-0084647

(51) Int. Cl. H01L 27/146

(52) U.S. Cl. CPC H01L 27/14618; H01L 27/14627; H01L 27/14634

(57) ABSTRACT

Provided is a semiconductor package including: a substrate; an image sensor chip disposed on the substrate and including a first surface that faces the substrate and a second surface that is opposed to the first surface; an adhesion layer interposed between the substrate and the image sensor chip; and a first cavity surrounded by the first surface, an upper surface of the substrate and a side surface of the adhesion layer. The first surface includes a first central portion and a first edge portion, the adhesion layer includes a first adhesion part directly contacting the first central portion and a second adhesion part directly contacting the substrate, and the first adhesion part has an area corresponding to about 5% to about 50% of an area of the first surface.

### CROSS-REFERENCE TO RELATED APPLICATIONS

This U.S. non-provisional patent application claims priority under 35 U.S.C. §119 of Korean Patent Application No. 10-2014-0084647, filed on Jul. 7, 2014, the disclosure of which is hereby incorporated by reference in its entirety.

### BACKGROUND

The present disclosure herein relates to a semiconductor device, and more particularly, to a semiconductor package and a method for manufacturing the same.

An image sensor, such as a CCD sensor or a CMOS sensor are used in various electronic products, such as mobile phones, digital cameras, optical mice, security cameras, and biometric devices. As electronic products are miniaturized and multi-functionalized, a semiconductor package including an image sensor requires miniaturization/high density, low power consumption, multi-functionality, high-speed signal processing, high reliability, low price and clear image quality. Various studies are performed corresponding to such requirements.

### SUMMARY

The present disclosure provides a semiconductor package capable of improving a degree of warpage of an image sensor chip.

The present disclosure also provides a method for manufacturing capable of reducing the warpage of an image sensor chip.

Embodiments of the inventive concept provide a semiconductor package including: a substrate; an image sensor chip disposed on the substrate and including a first surface that faces the substrate and a second surface that is opposed to the first surface; an adhesion layer interposed between the substrate and the image sensor chip; and a first cavity surrounded by the first surface, an upper surface of the substrate and a side surface of the adhesion layer, wherein the first surface comprises a first central portion and a first edge portion, and the adhesion layer comprises a first adhesion part or portion directly contacting the first central portion and a second adhesion part or portion directly contacting the upper surface of the substrate, wherein the first adhesion part has an area corresponding to about 5% to about 50% of an area of the first surface.

In some embodiments, the substrate may include a second central portion and a second edge portion, and the second adhesion part directly contacts the second central portion.

In some embodiments, the adhesion layer may have a thickness of about 1 μm to about 80 μm, and the second adhesion part may have an area greater than that of the first adhesion part.

In some embodiments, the first adhesion part may be spaced apart from the first edge portion, and may have a circular shape on the image sensor chip first surface.

In some embodiments, the adhesion layer may have a modulus of about 2.7 MPa to about 4.2 MPa at a temperature of about −60° C. to about 230° C.

In some embodiments, the substrate may be a plastic substrate.

In some embodiments, the plastic substrate may be a printed circuit board (PCB).

In some embodiments, the substrate may have a thermal expansion coefficient of about 13 ppm/° C. or less at room temperature.

In some embodiments, the image sensor may have a warpage of about 10 μm or less.

In some embodiments, the semiconductor package may further include: a holder having an upper surface spaced apart from the second surface of the image sensor chip; and a transparent substrate disposed so as to be adjacent to the upper surface of the holder.

In some embodiments, the semiconductor package may further include: a second cavity surrounded by the transparent substrate, the holder and the image sensor chip.

In some embodiments, the substrate, the image sensor chip, the adhesion layer, the holder and the transparent substrate may be comprised of materials having different material characteristics.

In some embodiments, the semiconductor package may further include: a transparent substrate on the image sensor chip; and a mold film covering a side surface of the transparent substrate and a side surface of the image sensor chip, wherein the first cavity is surrounded by the first surface, the upper surface of the substrate, the side surface of the adhesion layer, and the mold film.

In other embodiments of the inventive concept, a semiconductor package includes: a substrate; an image sensor chip disposed on the substrate and including a first surface that faces the substrate and a second surface that is opposed to the first surface; and an adhesion layer interposed between the substrate and the image sensor chip, wherein the adhesion layer comprises a first adhesion part or portion directly contacting the first surface, wherein an area of the first adhesion part corresponds to about 5% to about 50% of an area of the first surface, and wherein the adhesion layer has an elastic modulus of about 2.7 MPa to about 4.2 MPa at a temperature of about −60° C. to about 230° C.

In some embodiments, the substrate may have a thermal expansion coefficient of about 13 ppm/° C. or less at room temperature.

In other embodiments of the inventive concept, a semiconductor package includes: a substrate; an image sensor chip on the substrate; an adhesion layer between the substrate and the image sensor chip. The substrate includes a printed circuit board (PCB) and first and second opposing sides. The image sensor chip includes a first side that faces the substrate and a second side opposing the first side. The first side of the image sensor chip comprises a first central portion and a first edge portion. The adhesion layer includes: a first adhesion surface directly contacting the first central portion and spaced apart from the first edge portion of the image sensor chip; and a second adhesion surface directly contacting the first side of the substrate.

In some embodiments, the semiconductor package may include: a holding member on the substrate, the holding member including an upper surface spaced apart from the second side of the image sensor chip; and a transparent substrate on the upper surface of the holding member.

In some embodiments, the semiconductor package may include: a transparent substrate on the image sensor chip; and a mold film covering at least a portion of a side surface of the transparent substrate and a side surface of the image sensor chip. The first side of the image sensor chip, the first side of the substrate, the side surface of the adhesion layer, and the mold film may define a first cavity.

In some embodiments, the semiconductor package may include a microlens array in a recessed region defined in the second side of the image sensor chip.

In some embodiments, the first adhesion surface has an area of about 5% to about 50% of an area of the first side of the image sensor chip.

In still other embodiments of the inventive concept, a method for manufacturing a semiconductor package includes: preparing a substrate; forming an adhesion layer on the substrate; and attaching an image sensor chip on the substrate by using the adhesion layer, wherein the mounting the image sensor chip allows the adhesion layer to form a circular shape as viewed from a plan view, and the attaching image sensor is performed such that a coverage ratio in which the adhesion layer covers a lower surface of the image sensor chip is about 5% to about 50%.

In some embodiments, the forming the adhesion layer may be performed by using an epoxy resin having a modulus of about 2.7 MPa to about 4.2 MPa at a temperature of about −60° C. to about 230° C.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a cross-sectional view illustrating a ceramic semiconductor package mounted with an image sensor chip according to some embodiments of the inventive concept;

FIG. 1B is a cross-sectional view of a semiconductor package according to some embodiments of the inventive concept;

FIGS. 2A to 2D are graphs showing that effective factors influence a warpage of an image sensor chip according to an experimental example of the inventive concept;

FIG. 2E is a graph showing maximum warpage with respect to a combination of three effective factors generating an interaction effect according to an experimental example of the inventive concept;

FIG. 3A is a plan view illustrating a semiconductor package according to Embodiment 1 of the inventive concept;

FIG. 3B is a cross-sectional view taken along a line A-A′ of FIG. 3A;

FIGS. 4A to 4E are cross-sectional views sequentially illustrating processes of manufacturing a semiconductor package according to Embodiment 1 of the inventive concept;

FIG. 5A is a plan view illustrating a semiconductor package according to Embodiment 2 of the inventive concept;

FIG. 5B is a cross-sectional view taken along a line A-A′ of FIG. 5A;

FIGS. 6A to 6F are cross-sectional views sequentially illustrating processes of manufacturing a semiconductor package according to Embodiment 2 of the inventive concept; and

FIGS. 7 to 11 are perspective views illustrating multimedia devices to which a semiconductor package according to some embodiments of the inventive concept is applied.

### DETAILED DESCRIPTION OF THE EMBODIMENTS

Preferred embodiments of the inventive concept will be described below in more detail with reference to the accompanying drawings in order to fully understand the constitution and effect of the inventive concept. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

In addition, it will be understood that when an element is referred to as being “on” another element, it can be directly on the other element or intervening elements may also be present. In contrast, when an element is referred to as being “directly on” another element, there are no intervening elements present. Like reference numerals refer to like elements throughout.

Additionally, the embodiments in the detailed description will be described with sectional views and/or plain views as ideal exemplary views of the inventive concept. In the figures, the dimensions of elements, layers and regions may be exaggerated for clarity of illustration. Areas exemplified in the drawings may have general properties, and may be used to illustrate a specific shape of a semiconductor package region. Thus, this should not be construed as limiting the scope of the inventive concept. It will be understood that although the terms first, second and third are used herein to describe various elements, these elements should not be limited by these terms. These terms are used only to distinguish one element, region or layer from another element, region or layer.

In the following description, the technical terms are used only for explaining a specific exemplary embodiment while not limiting the inventive concept. The terms of a singular form may include plural forms unless referred to the contrary. It will be understood that the terms “include,” “comprise,” “including,” or “comprising,” when used in this specification, specify the presence of stated features, integers, steps, operations, elements, and/or components, but do not preclude the presence or addition of one or more other features, integers, steps, operations, elements, components, and/or groups thereof.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

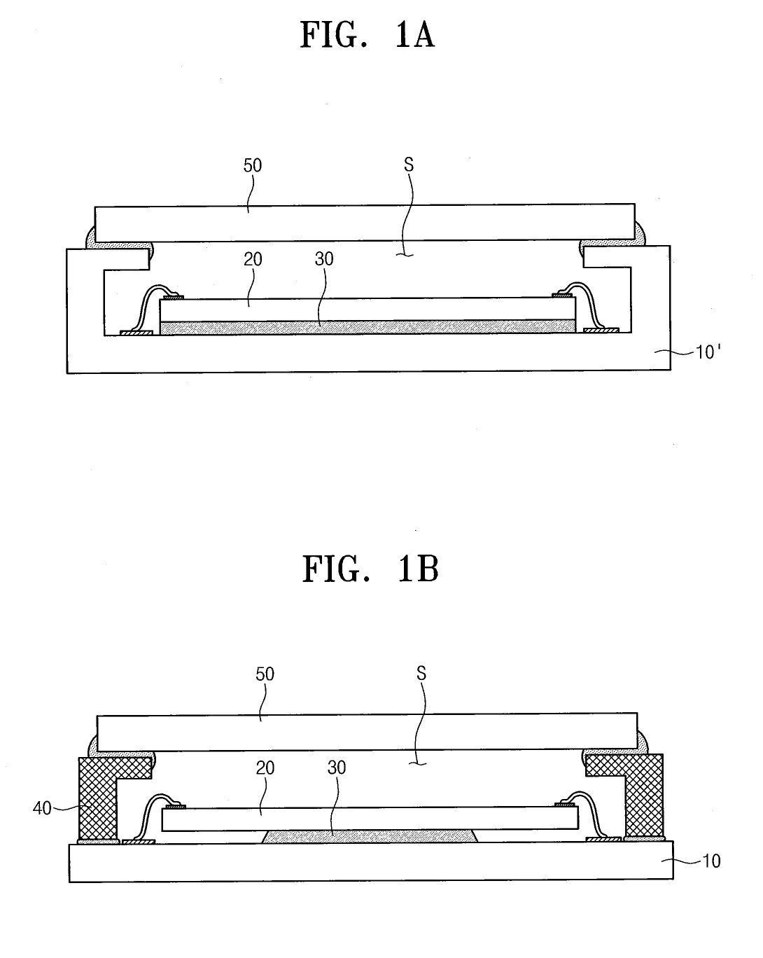

FIG. 1A is a cross-sectional view illustrating a ceramic semiconductor package mounted with an image sensor chip according to an example of the inventive concept.

Referring to FIG. 1A, a ceramic semiconductor package may include a ceramic substrate 10′, an image sensor chip 20 disposed on the ceramic substrate 10′, and an adhesion layer 30 interposed between the ceramic substrate 10′ and the image sensor chip 20. An uppermost portion of the ceramic substrate 10′ may be further spaced apart upward from a surface of the image sensor chip 20 (e.g., a top surface of the image sensor chip 20), and a transparent substrate 50 may be disposed so as to be adjacent the uppermost portion of the ceramic substrate 10′. Therefore, a cavity S surrounded by the ceramic substrate 10′ and the transparent substrate 50 may be defined. The adhesion layer 30 may be formed so as to directly contact an entire lower surface of the image sensor chip 20. The adhesion layer 30 may be comprised of an epoxy resin.

FIG. 1B is a cross-sectional view of a semiconductor package according to an example of the inventive concept.

Referring to FIG. 1B, a ceramic semiconductor package may include a substrate 10, an image sensor chip 20 disposed on the substrate 10, an adhesion layer 30 interposed between the substrate 10 and the image sensor chip 20, a holder or holding member 40 having an upper surface spaced apart from a surface of the image sensor chip 20 (e.g., a top surface of the image sensor chip 20) and a transparent substrate 50 disposed so as to be adjacent to the upper surface of the holder 40. Further, a cavity S surrounded by the substrate 10, the holder 40, and the transparent substrate 50 may be defined. The adhesion layer 30 may be formed so as to directly contact an entirety or a part of a lower surface of the image sensor chip 20. The substrate 10 may be a plastic substrate, and in more detail, may be a printed circuit board (PCB). The holder 40 may be a plastic holder. The adhesion layer 30 may be comprised of an epoxy resin.

Meanwhile, in an imaging device, such as a DSLR camera, a warpage phenomenon of an image sensor chip in the semiconductor package may occur. The warpage of the image sensor chip may cause resolution and shading differences between a central portion and a peripheral portion in an output image of the image sensor.

In the semiconductor package according to FIG. 1B, the substrate 10, the image sensor chip 20, the adhesion layer 30, the holder 40 and the transparent substrate 50 may be comprised of materials having different characteristics from one another. Therefore, in the semiconductor package according to FIG. 1B, the warpage of the image sensor chip 20 due to deterioration may be more serious than the ceramic semiconductor of FIG. 1A configured with a frame of the package that is comprised of one ceramic material.

In the semiconductor package according to FIG. 1B, the warpage problem of the image sensor chip 20 may be influenced by various factors. Meanwhile, the inventors have confirmed that three factors including a thermal expansion coefficient (CTE) of the substrate 10, a modulus of the adhesion layer 30 (e.g., an elastic modulus of the adhesion layer 30) and a coverage ratio in which the adhesion layer 30 covers the lower surface of the image sensor chip 20, are main factors that influence the warpage of the image sensor chip 20. Furthermore, the inventors have confirmed that the three factors complexly interact with each other to generate an interaction effect on the warpage of the image sensor chip 20.

### Experimental Example 1

In the semiconductor package according to FIG. 1B, the warpage of the image sensor chip 20 was measured while each of a thermal expansion coefficient of the substrate 10, a modulus of the adhesion layer 30 (e.g., an elastic modulus of the adhesion layer 30), a coverage ratio of the adhesion layer 30 and a thermal expansion coefficient of the transparent substrate 50 was varied.

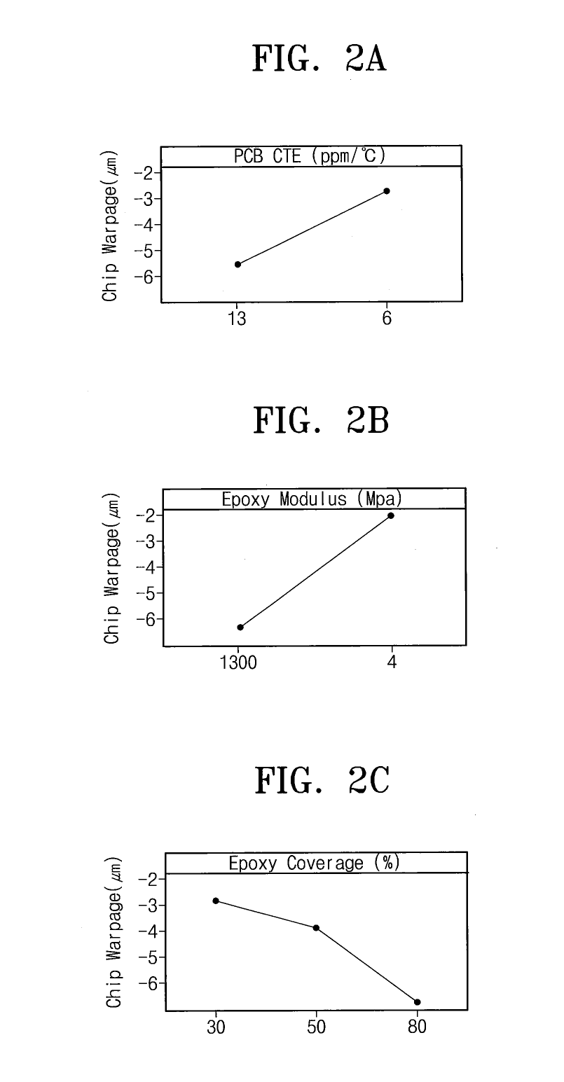

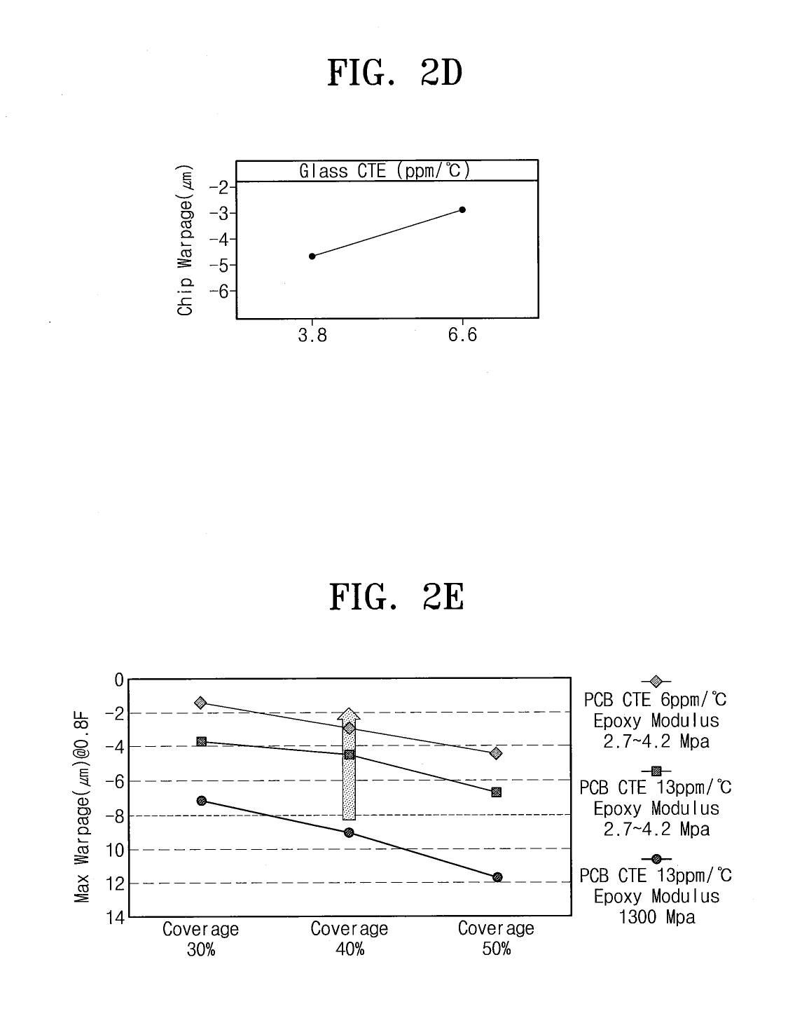

FIG. 2A is a result showing the warpage of the image sensor chip 20 when a PCB is used as the substrate 10 and a thermal expansion coefficient is varied from about 6 ppm/° C. to about 13 ppm/° C. at room temperature. As used herein, the term “room temperature” may refer to a temperature from about 20° C. to about 23° C. It may be confirmed that the more a thermal expansion coefficient of the PCB is reduced, the more the warpage of the image sensor chip 20 is reduced. As used herein, the term “warpage” may refer to the displacement of the image sensor chip 20 or a portion thereof relative to the image sensor chip 20 in its flat or “non-warped” state.

FIG. 2B is a result showing the warpage of the image sensor chip 20 when the adhesion layer 30 is formed by using an epoxy resin having a modulus of about 2.7 MPa to about 4.2 MPa, or an epoxy resin having a modulus of about 1300 MPa. It may be confirmed that the more a modulus of the adhesion layer 30 is reduced, the more the warpage of the image sensor chip 20 is reduced.

FIG. 2C is a result showing the warpage of the image sensor chip 20 when the adhesion layer 30 is formed while the coverage ratio of the adhesion layer 30 is varied from about 30% to about 80% with respect to the lower surface of the image sensor chip 20. It may be confirmed that the more the coverage ratio of the adhesion layer 30 is reduced, the more the warpage of the image sensor chip 20 is reduced, and as the coverage ratio is reduced by about 10%, the warpage of the image sensor chip 20 is reduced by about 1 μm.

FIG. 2D is a result showing the warpage degree of the image sensor chip 20 when glass is used as the transparent substrate 50 and the thermal expansion coefficient is varied from about 3.8 ppm/° C. to about 6.6 ppm/° C. at room temperature. It may be confirmed that the more the thermal expansion coefficient of the glass substrate is increased, the more the warpage of the image sensor chip 20 is reduced.

### Experimental Example 2

In the semiconductor package according to FIG. 1B, the warpage of the image sensor chip 20 was measured while each of the thermal expansion coefficient of the substrate 10, the modulus of the adhesion layer 30 (e.g., an elastic modulus of the adhesion layer 30), the coverage ratio of the adhesion layer 30 and the thermal expansion coefficient of the transparent substrate 50 was varied. A PCB substrate was used as the substrate 10, the adhesion layer 30 was formed by using an epoxy resin, and a glass substrate was used as the transparent substrate 50.

The result is shown in Table 1 and FIG. 2E described below.

TABLE 1

| | | | Substrate | | | Transparent |
|---|---|---|---|---|---|---|
| | Ave | Max | (PCB) | Modulus of | | substrate |
| | warpage | warpage | CTE | adhesion layer | Coverage | (Glass) CTE |
| Classification | (μm) | (μm) | (ppm/° C.) | epoxy (MPa) | ratio (%) | (ppm/° C.) |
| G1 | −0.26 | −2.20 | 6 | 2.7-4.2 | 30% | 3.8 |
| G2 | −2.44 | −3.56 | 13 | 2.7-4.2 | 30% | 3.8 |
| G3 | −3.42 | −4.42 | 6 | 1300 | 30% | 3.8 |
| G4 | −5.69 | −7.12 | 13 | 1300 | 30% | 3.8 |
| G5 | −1.21 | −2.90 | 6 | 2.7-4.2 | 40% | 3.8 |
| G6 | −3.01 | −4.01 | 13 | 2.7-4.2 | 40% | 3.8 |
| G7 | −4.57 | −6.06 | 6 | 1300 | 40% | 3.8 |
| G8 | −7.38 | −9.01 | 13 | 1300 | 40% | 3.8 |
| G9 | −2.90 | −4.47 | 6 | 2.7-4.2 | 50% | 3.8 |
| G10 | −5.41 | −6.70 | 13 | 2.7-4.2 | 50% | 3.8 |
| G11 | −6.56 | −7.74 | 6 | 1300 | 50% | 3.8 |
| G12 | −10.41 | −11.67 | 13 | 1300 | 50% | 3.8 |
| G13 | 0.38 | −1.41 | 6 | 2.7-4.2 | 30% | 6.6 |
| G14 | −3.91 | −5.63 | 6 | 1300 | 40% | 6.6 |
| G15 | −2.42 | −4.49 | 13 | 2.7-4.2 | 40% | 6.6 |
| G16 | −5.56 | −7.03 | 13 | 1300 | 30% | 6.6 |

Referring to Table 1, it may be confirmed that the thermal expansion coefficient (CTE) of the substrate 10, the modulus of the adhesion layer 30 and the coverage ratio in which the adhesion layer 30 covers the lower surface of the image sensor chip 20 are effective factors that influence the warpage and concurrently generate an interaction effect. However, according to the experimental example 1, it may be confirmed that the thermal expansion coefficient (CTE) of the transparent substrate 50 is an effective factor influencing the warpage, but does not represent an overlapping effect. For example, in comparison between G6 and G5, it may be confirmed that as the thermal expansion coefficient of the substrate (PCB) 10 is reduced, the maximum warpage (Max warpage) is improved by 1.11 μm, and the average degree of warpage (Ave warpage) is improved by about 1.8 μm. Meanwhile, in comparison between G6 and G15, it may be confirmed that as the thermal expansion coefficient of the transparent substrate (Glass) 50 is increased, the maximum warpage is improved by 0.48 μm, and the average degree of warpage degree is improved by about 0.59 μm. Even if a factor is an effective factor influencing the warpage, it may be seen that a combination of effective factors capable of generating a synergy effect is restrictive.

FIG. 2E is a graph showing maximum warpage with respect to a combination of three effective factors (a thermal expansion coefficient of a substrate 10, a modulus of an adhesion layer 30 and a coverage ratio of the adhesion layer 30).

Referring to FIG. 2E, it may be confirmed that an overlapping effect of the three effective factors represents a linear relationship. That is, the three effective factors may be combined to each other to generate a synergy effect.

Hereinafter, exemplary embodiments of the inventive concept will be described in detail with reference to accompanying drawings.

### Example Embodiment 1

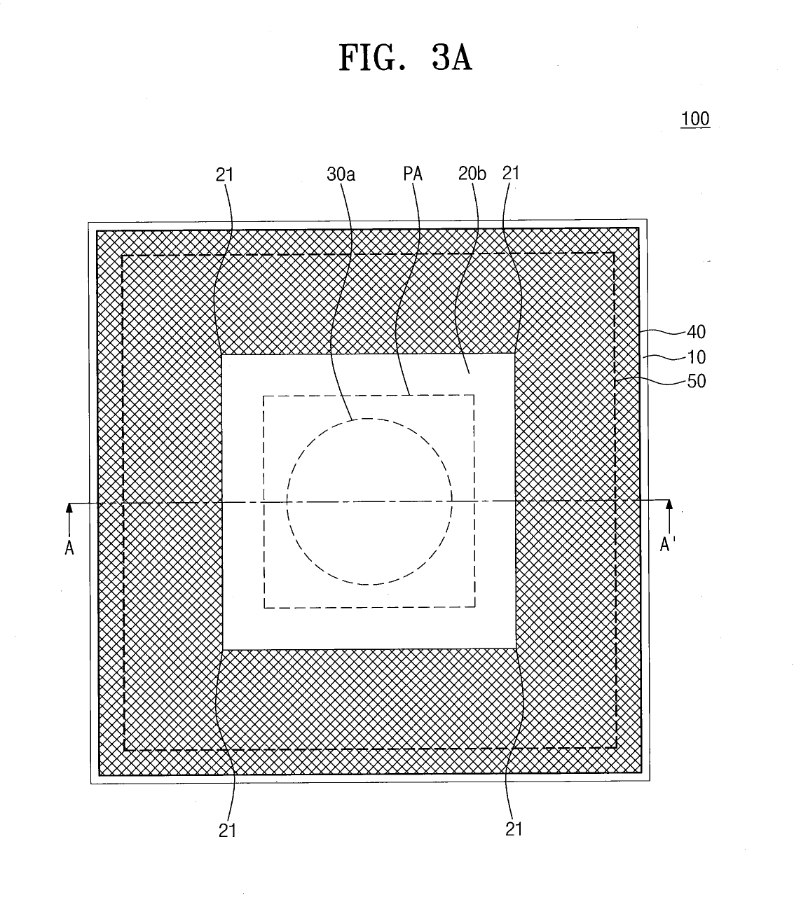

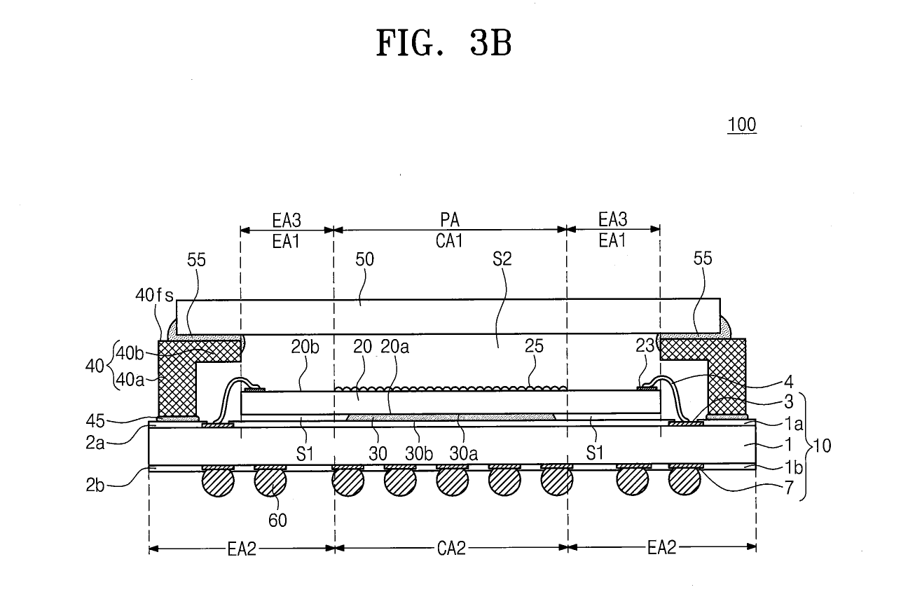

FIG. 3A is a plan view illustrating a semiconductor package according to Embodiment 1 of the inventive concept. FIG. 3B is a cross-sectional view taken along a line A-A′ of FIG. 3A.

Referring to FIGS. 3A and 3B, a semiconductor package 100 according to Embodiment 1 of the inventive concept may include a substrate 10, an image sensor chip 20 mounted on the substrate 10, and an adhesion layer 30 interposed between the substrate 10 and the image sensor chip 20. The substrate 10 may include a substrate body 1, and a first or upper surface 1a and a second or lower surface 1b opposed to each other. Furthermore, the substrate 10 may include a second central portion CA2 and a second edge or peripheral portion EA2. The second central portion CA2 may overlap or be aligned with a first central portion CA1 to be described below, or may correspond to the first central portion CA1. The second edge portion EA2 may overlap or be aligned with a first edge or peripheral portion EA1 to be described below. The substrate body 1 may be formed of an insulation material such as a plastic material. A conductive via (not shown), or at least one layered conductive circuit pattern (not shown) may be disposed inside the substrate body 1. A first substrate connection terminal 3 may be disposed on the upper surface 1a, and a second substrate connection terminal 7 may be disposed on the lower surface 1b. The upper surface 1a and the lower surface 1b may be covered with protection films 2a and 2b, respectively. The substrate 10 may be a plastic substrate. For example, the plastic substrate may be a printed circuit board (PCB). As described above, it may be preferable that a thermal expansion coefficient (CTE) of the substrate be 13 ppm/° C. or less at room temperature in order to improve (reduce) the warpage of the image sensor chip 20 (Experimental examples 1 and 2). Therefore, a thermal expansion coefficient of the substrate 10 may be 13 ppm/° C. or less at room temperature.

The image sensor chip 20 may include a first or lower surface 20a facing the substrate 10 and a second or upper surface 20b opposed to the first surface 20a. The first surface 20a may include a first central portion CA1 and a first edge or peripheral portion EA1, and the second surface 20b may include a pixel portion PA and a third edge or peripheral portion EA3. The first central portion CA1 may be aligned with or correspond to the pixel portion PA, and the first edge portion EA1 may be aligned with or correspond to the third edge portion EA3. Although not shown, a plurality of photoelectric conversion units and a plurality of transistors for transferring and processing a signal transmitted from the photoelectric conversion units may be disposed on the pixel portion PA of the image sensor chip 20. A micro lens array 25 may be disposed on the pixel portion PA. Peripheral circuits may be disposed on the first edge portion EA1 and/or the third edge portion EA3. A chip connection terminal 23 may be disposed on the third edge portion EA3 of the image sensor chip 20. In this embodiment, the image sensor chip 20 may be mounted on the substrate 10 through a wire bonding method. Thus, the chip connection terminal 23 and the first substrate connection terminal 3 may be connected by a wire 4.

The image sensor chip 20 may be attached on or to the upper surface 1a of the substrate 10 by disposing the adhesion layer 30 on the upper surface 1a. In more detail, the adhesion layer 30 may include a first or upper adhesion part, portion or surface 30a directly contacting the first central portion CA1 of the image sensor chip 20 and a second or lower adhesion part, portion or surface 30b directly contacting the second central portion CA2 of the substrate 10. That is, the first adhesion part 30a may be an upper surface of the adhesion layer 30, and the second adhesion layer 30b may be a lower surface of the adhesion layer 30. As described above, it may be preferable that a modulus of the adhesion layer 30 (e.g., an elastic modulus of the adhesion layer 30) be about 2.7 MPa to about 4.2 MPa at a temperature of about −60° C. to about 230° C. in order to improve (reduce) the warpage of the image sensor chip 20 (Experimental examples 1 and 2). Therefore, the adhesion layer 30 may have a modulus of about 2.7 MPa to about 4.2 MPa at a temperature of about −60° C. to about 230° C. In more detail, the modulus of the adhesion layer 30 may be a modulus of an adhesion material for forming the adhesion layer 30. Meanwhile, when the adhesion layer 30 has the modulus of about 2.7 MPa to about 4.2 MPa at a temperature of about −60° C. to about 230° C., the adhesion layer 30 may have viscosity lower than that of an adhesion layer having a modulus higher than the modulus thereof. That is, the adhesion layer 30 may be thinner than an adhesion layer having a modulus higher than the modulus thereof, and the second adhesion part 30b may have an area greater than that of the first adhesion part 30a. Thus, the adhesion layer 30 may have a cross-section having a trapezoid shape. The adhesion layer 30 may have a thickness of about 1 μm to about 80 μm. The adhesion layer 30 may be comprised of, for example, an epoxy resin.

The adhesion layer 30 may be spaced apart from the first edge portion EA1 when viewed from a plan view. That is, the first adhesion part 30A may cover only a part of the image sensor chip first surface 20a, and may not cover or reach the first edge portion EA1 on the first surface 20a. Furthermore, the adhesion layer 30 may have a circular shape when viewed from a plan view. That is, the first adhesion part 30a and the second adhesion part 30b may have a circular shape. When the adhesion layer 30 has a circular shape, the first adhesion part 30a may be spaced relatively far apart from each corner or vertex 21 of the first surface 20a. When the adhesion layer 30 has a square shape, a spaced apart distance from the vertices 21 is reduced, and thus a warpage phenomenon of the image sensor chip 20 may worsen.

As described above, it may be preferable that a coverage ratio of an adhesion layer covering a lower surface of an image sensor chip be not more than about 50% in order to improve (reduce) the warpage of the image sensor chip 20 (Experimental examples 1 and 2). Therefore, the first adhesion part 30a may have an area corresponding to about 5% to about 50% of an area of the image sensor chip first surface 20a. For example, when the area of the first adhesion part 30a is called “A”, and the area of the first surface 20a is called “B”, A/B may be about 0.05 to about 0.5.

The semiconductor package 100 according to an embodiment of the inventive concept may include a first cavity S1 surrounded by the image sensor chip first surface 20a, the upper surface 1a of the substrate 10 and a side surface of the adhesion layer 30. That is, since the first adhesion part 30a covers a part of the first surface 20a, the first cavity S1 may be an empty space defined below the image sensor chip 20. Furthermore, the first cavity S1 may further extend to be connected to or be in communication with a second cavity S2 surrounded by a transparent substrate 50, a holder or holding member 40 and the substrate 10. The degree of warpage of the image sensor chip 20 may be improved due to the first cavity S1 defined below the image sensor chip 20.

The holder 40 may be disposed on the upper surface 1a of the substrate 10. The holder 40 may have an upper surface 40fs spaced apart from a surface of the image sensor chip 20. In more detail, the holder 40 may include an outer or outside cover portion 40a adjacent to the third edge portion EA3 and formed on the upper surface 1a, and an upper cover portion 40b connected to the outside cover portion 40a and adjacent to the transparent substrate 50. The spaced upper surface 40fs may be an upper surface of the upper cover portion 40b. The outside cover portion 40a and the upper cover portion 40b may be integrally connected to each other. Although not shown, at least a part of the third edge portion EA3 of the image sensor chip 20 may be covered by the holder 40 when viewed from a plan view. For example, the holder 40 may cover the third edge portion EA3, and may expose the pixel portion PA. The holder 40 may have a closed curve shape (or generally square shape) as viewed from a plan view. The holder 40 may be a plastic holder, and in more detail, may be formed of a polymer material such as polyamide. The holder 40 may be attached on the second edge portion EA2 of the substrate 10 by disposing a first adhesion film 45 on the second edge portion EA2.

The holder 40 may help isolate the image sensor chip 20 from the outside, and thus may help prevent an outside foreign substance from entering the pixel portion PA. Thus, a pixel distortion caused due to pollution by a foreign substance may be prevented. Furthermore, the holder 40 may protect a bonding between the wire 4 and the chip connection terminal 23 and a bonding between the wire 4 and the first substrate connection terminal 3 from the outside.

The transparent substrate 50 may be disposed on the upper cover portion 40b to thus provide the second cavity S2 between the transparent substrate 50 and the image sensor chip 20. In more detail, the transparent substrate 50 may be disposed so as to be adjacent to the upper surface 40fs of the holder 40. The transparent substrate 50 may be formed of transparent glass, plastic or the like. A second adhesion film 55 may be interposed between an edge or peripheral portion of the transparent substrate 50 and the upper surface 40fs of the holder 40. The second adhesion film 55 may include the same material as the first adhesion film 45. The second adhesion film 55 may extend to cover at least a portion of a side surface of the transparent substrate 50 and/or at least a portion of a side surface of the upper cover portion 40b. Thus, an area on which the second adhesion film 55 contacts the transparent substrate 50 and/or the holder 40 may become wider to enhance an adhesion force.

A solder bump 60 may be attached to the second substrate connection terminal 7 of the substrate 10.

The semiconductor package 100 according to an embodiment of the inventive concept may adjust three factors including a coefficient of thermal expansion of the substrate 10, a modulus of the adhesion layer 30 (e.g., an elastic modulus of the adhesion layer 30) and a coverage ratio of the adhesion layer 30 with respect to the image sensor 20 to considerably improve (reduce) the warpage by using an interaction effect of the three factors.

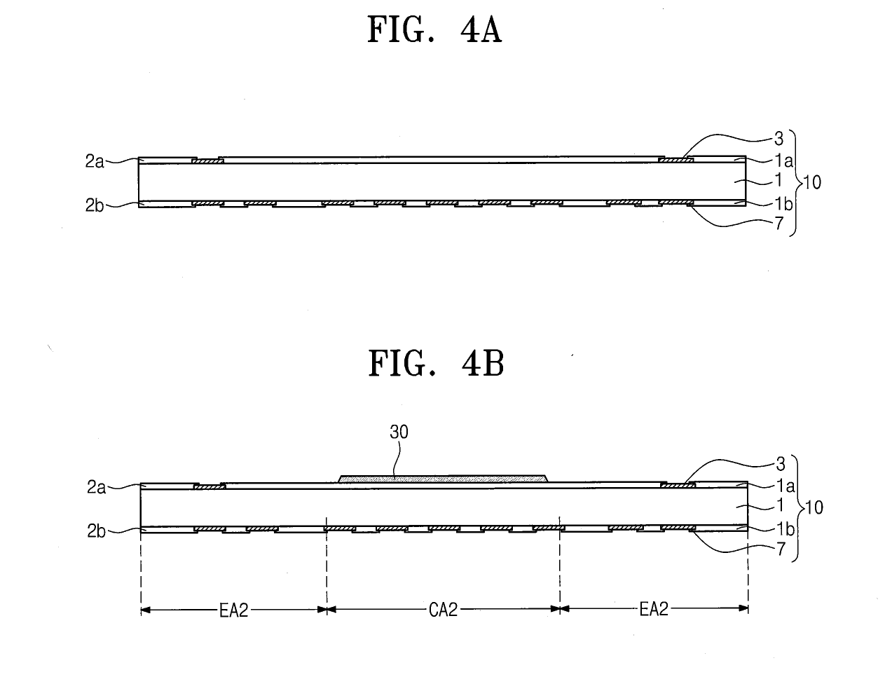

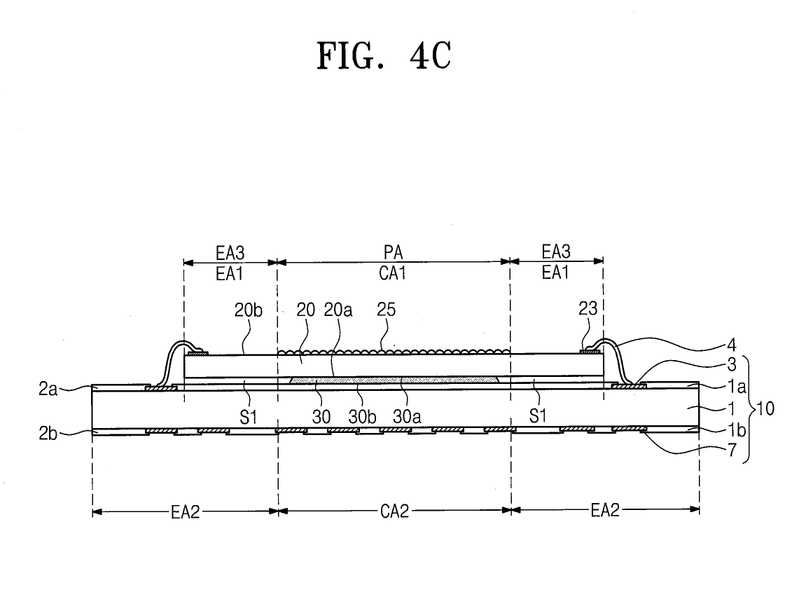

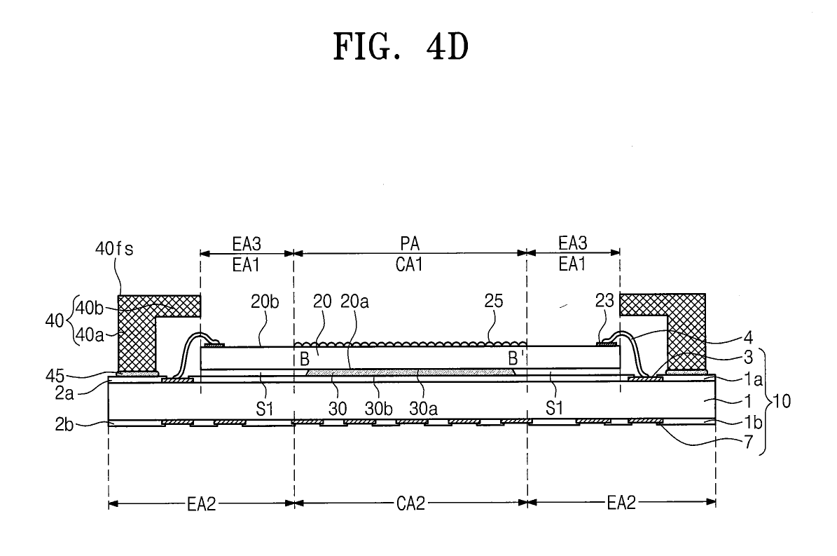

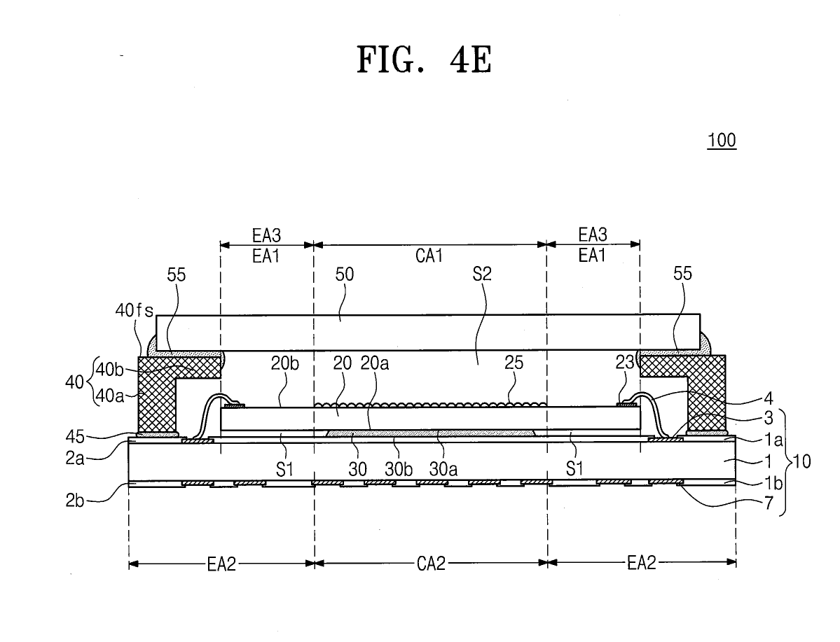

FIGS. 4A to 4E are views sequentially illustrating processes of manufacturing a semiconductor package 100 according to Embodiment 1 of the inventive concept.

Referring to FIG. 4A, firstly, a substrate 10 may be prepared. The substrate 10 may include a substrate body 1, and an upper surface 1a and a lower surface 1b opposed to each other. The substrate body 1 may be formed of an insulation material such as a plastic material. A conductive via (not shown), or at least one layered conductive circuit pattern (not shown) may be disposed inside the substrate body 1. A first substrate connection terminal 3 may be disposed on the substrate upper surface 1a, and a second substrate connection terminal 7 may be disposed on the substrate lower surface 1b. The upper surface 1a and the lower surface 1b may be covered with protection films 2a and 2b, respectively. The substrate 10 may be a plastic substrate. For example, the plastic substrate may be a printed circuit board (PCB). Other details regarding the substrate 10 are the same as those described above with reference to FIGS. 3A and 3B.

Referring to FIG. 4B, an adhesion layer 30 may be formed on the substrate 10. The adhesion layer 30 may be formed by applying an adhesive material on a second central portion CA2 of the substrate 10. The adhesive material may have a modulus (e.g., an elastic modulus) of 2.7 MPa to 4.2 MPa at a temperature of about −60° C. to about 230° C. The adhesive material may have a relatively low modulus, and thus may have relatively low viscosity. Therefore, the adhesion layer 30 may have a cross-section having a trapezoid shape. The adhesion layer 30 may be formed spaced apart from the second edge portion EA2 of the substrate 10. The adhesion layer 30 may have an appropriate shape so as to form a circle when viewed from a plan view when an image sensor is later disposed on the adhesion layer 30. For example, the adhesion layer 30 may be formed in a star shape. The adhesion layer 30 may be comprised of an epoxy resin.

Referring to FIG. 4C, an image sensor chip 20 may be attached on the substrate 10 by using the adhesion layer 30. The image sensor chip 20 may include a first surface 20a facing the substrate 10 and a second surface 20b opposed to the first surface 20a. The first surface 20a may include a first central portion CA1 and a first edge portion EA1, and the second surface 20b may include a pixel portion PA and a third edge portion EA3. Although not shown, a plurality of photoelectric conversion units and a plurality of transistors for transferring and processing a signal transmitted from the photoelectric conversion units may be disposed on the pixel portion PA of the image sensor chip 20. A micro lens array 25 may be disposed on the pixel portion PA. Other details regarding the image sensor chip 20 are the same as those described above with reference to FIGS. 3A and 3B.

The image sensor chip 20 may be disposed such that the first central portion CA1 on the first surface 20a thereof directly contacts a first adhesion part 30a of the adhesion layer 30. When the image sensor chip 20 is disposed on the adhesion layer 30, the adhesion layer 30 may be applied with a pressure to be spread in an outward direction. At this time, when the adhesion layer 30 is formed in a star shape, the image sensor chip 20 is disposed on the adhesion layer 30, and thus the adhesion layer 30 may be changed into a circular shape. When the adhesion layer 30 has a circular shape as viewed from a plan view, the warpage of the image sensor chip 20 may be improved as described above. Furthermore, the first adhesion part 30a of the adhesion layer 30 may have an area corresponding to about 5% to about 50% of an area of the first surface 20a of the image sensor chip 20. Meanwhile, since the first adhesion part 30a covers only a part of the first surface 20a, a first cavity S1 surrounded by the first surface 20a, the upper surface 1a of the substrate 10 and the side surface of the adhesion layer 30 may be defined.

After the image sensor chip 20 is attached, a wire bonding may be performed to form a wire 4 connecting a chip connection terminal 23 and a first substrate connection terminal 3.

Referring to FIG. 4D, a holder 40 may be formed on the upper surface 1a of the substrate 10. The holder 40 may include an outside cover portion 40a adjacent to the third edge portion EA3 and formed on the upper surface 1a and an upper cover portion 40b connected to the outside cover portion 40a. The upper cover portion 40b may have an upper surface 40fs spaced apart from a surface of the image sensor chip 20. The holder 40 may be a plastic holder, and in more detail, may be formed of a polymer material such as polyamide. The holder 40 may be attached on or to the second edge portion EA2 of the substrate 10 by disposing a first adhesion film 45 on the second edge portion EA2. In addition, a process of curing the first adhesion film 45 may be performed. For this purpose, a process of irradiating ultraviolet rays or a heating process may be performed. When the holder 40 is attached, since the attaching is performed in a state that the holder 40 is spaced apart from the pixel portion PA, the pixel portion PA may be prevented from being damaged or polluted. After the holder 40 is attached, a cleaning process may be performed by using cleaning liquid. Other details regarding the holder 40 are the same as those described above with reference to FIGS. 3A and 3B.

Referring to FIG. 4E, a second adhesion film 55 may be applied on the upper cover portion 40b of the holder 40. After the second adhesion film 55 is formed, a transparent substrate 50 may be disposed on the holder 40. At this time, the transparent substrate 50 may be disposed such that an edge portion thereof overlaps the upper cover portion 40b. The second adhesion film 55 may be formed of the same or similar material and formed in the same or similar method as the first adhesion film 45. The transparent substrate 50 may be formed of transparent glass, plastic or the like. The second adhesion layer 55 may be compressed by pressing the transparent substrate 50. Thus, while the second adhesion film 55 is compressed, the second adhesion film 55 may cover at least a portion of a side surface of the transparent substrate 50 and/or at least a portion of a side surface of the upper cover portion 40b. Subsequently, a process of curing the second adhesion film 55 may be performed. For this process, a process of irradiating ultraviolet rays or a heating process may be performed. Other details regarding the transparent substrate 50 are the same as those described above with reference to FIGS. 3A and 3B.

Next, referring to FIG. 3B, solder bumps 60 may be attached to the second substrate connection terminal 7.

### Example Embodiment 2

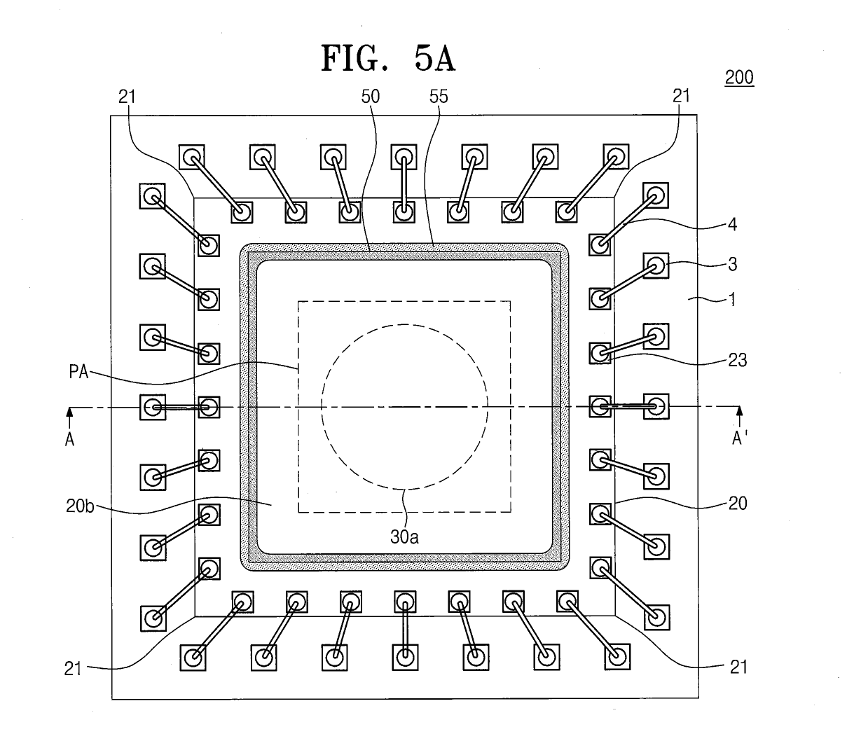

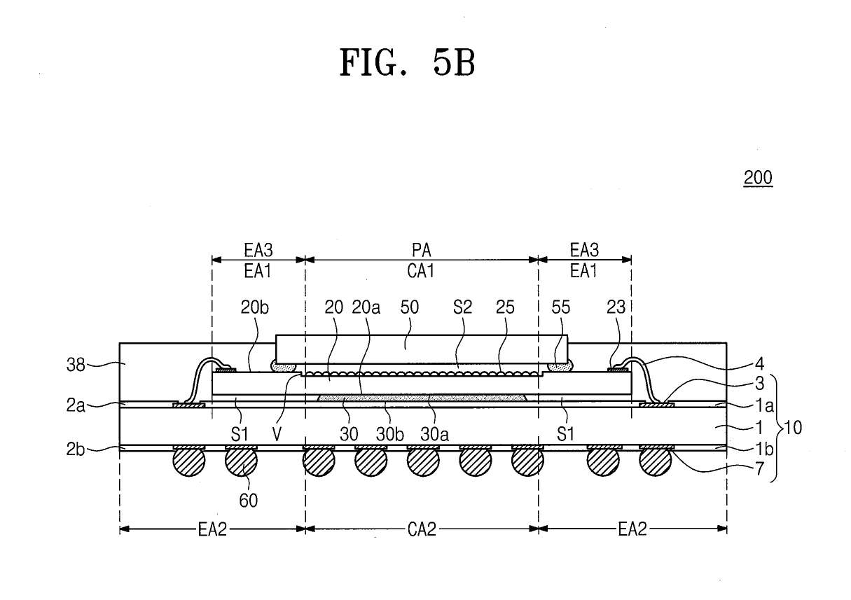

FIG. 5A is a plan view illustrating a semiconductor package according to Embodiment 2 of the inventive concept. FIG. 5B is a cross-sectional view taken along a line A-A′ of FIG. 5A.

A semiconductor package 200 according to Embodiment 2 of the inventive concept will be described with reference to FIGS. 5A and 5B. However, it is noted that, in the interest of brevity, the description will be made primarily based on elements different from those constituting the semiconductor package according to Embodiment 1 of the inventive concept, and other details are the same as those described above with reference to FIGS. 3A and 3B.

Referring to FIGS. 5A and 5B, a semiconductor package 200 according to Embodiment 2 of the inventive concept may include a substrate 10, an image sensor chip 20 mounted on the substrate 10 and an adhesion layer 30 interposed between the substrate 10 and the image sensor chip 20. The substrate 10 may have a thermal expansion coefficient of about 13 ppm/° C. or less at room temperature. The substrate 10 may be a plastic substrate. For example, the plastic substrate may be a printed circuit board (PCB).

The image sensor chip 20 may include a first surface 20a facing the substrate 10 and a second surface 20b opposed to the first surface 20a. Here, the second surface 20b may include a pixel portion PA and a third edge portion EA3. A recess or recessed region V may be formed on the pixel portion PA of the second surface 20b, and a micro lens array 25 may be disposed inside the recess region V.

The pixel portion PA of the image sensor chip 20 may be covered with a transparent substrate 50. The transparent substrate 50 may have a width narrower than that of the image sensor chip 20 (or an area less than that of the image sensor chip 20). The transparent substrate 50 may expose a part of the third edge portion EA3 and a chip connection terminal 23. A second cavity S2 may be defined between the transparent substrate 50 and the pixel portion PA. A second adhesion film 55 may be interposed between an edge or peripheral portion of the transparent substrate 50 and the third edge portion EA3 of the image sensor chip 20. The second cavity S2 between the transparent substrate 50 and the pixel portion PA may be closed or sealed by the second adhesion film 55.

The image sensor chip 20 may be attached on the upper surface 1a of the substrate 10 by disposing the adhesion layer 30 on the upper surface 1a. The adhesion layer 30 may include a first adhesion part or portion 30a directly contacting the first central portion CA1 and a second adhesion part or portion 30b directly contacting the second central portion CA2. The adhesion layer 30 may have a modulus (e.g., an elastic modulus) of about 2.7 MPa to about 4.2 MPa at a temperature of about −60° C. to about 230° C. The second adhesion part 30b may have an area greater than that of the first adhesion layer 30a, and thus the adhesion layer 30 may have a cross-section having a trapezoid shape. Furthermore, the adhesion layer 30 may have a thickness of about 1 μm to about 80 μm.

The adhesion layer 30 may be spaced apart from the first edge portion EA1 of the image sensor 20 when viewed from a plan view. Furthermore, the adhesion layer 30 may have a circle shape. In this case, the warpage of the image sensor chip 20 may be improved (reduced) as described above.

The first adhesion part 30a may have an area corresponding to 5% to 50% of an area of the image sensor chip first surface 20a. For example, when the area of the first adhesion part 30a is called “A”, and the area of the first surface 20a is called “B”, A/B may be about 0.05 to about 0.5. Thus, a first cavity S1 being an empty space formed below the image sensor chip 20 may be defined.

At least a part of a side surface of the transparent substrate 50, a part of the third edge portion EA3 of the image sensor 20 and a part of the second edge portion EA2 of the substrate 10 may be covered with a mold film 38. Since the mold film 38 may extend from the side surface of the transparent substrate 50 onto the third edge portion EA3, a side surface of the image sensor 20 may be also covered with the mold film 38. However, as described above, since the adhesion layer 30 may have a relatively low modulus, the adhesion layer 30 may have a relatively small thickness. Therefore, the mold film 38 may not cover the first central portion CA1 and the first edge portion EA1 of the image sensor chip 20. Alternatively, the mold film 38 may cover only a part of the first edge portion EA1. The first cavity S1 surrounded by the first surface 20a of the image sensor chip 20, the upper surface 1a of the substrate 10, the side surface of the adhesion layer 30, and the mold film 38 may be defined. The warpage of the image sensor chip 20 may be improved (reduced) due to the first cavity S1 defined below the image sensor chip 20.

Furthermore, the mold film 38 may cover the chip connection terminal 23, a first substrate connection terminal 3 and a wire 4. Thus, the mold film 38 may protect a bonding between the wire 4 and the chip connection terminal 23 and a bonding between the wire 4 and the first substrate connection terminal 3 from the outside.

Although not shown, an upper surface of the mold film 38 may be coplanar with an upper surface of the transparent substrate 50. Therefore, upper surfaces of the mold film 38 and the transparent 50 may be flat and coplanar. Alternatively, the upper surface of the mold film 38 may be located below or on a level lower than that of the upper surface of the transparent substrate 50. The mold film 38 may be formed by using an epoxy resin.

The semiconductor package 200 according to an embodiment of the inventive concept may adjust three factors including a coefficient of thermal expansion of the substrate 10, a modulus of the adhesion layer 30 (e.g., an elastic modulus of the adhesion layer 30) and a coverage ratio of the adhesion layer 30 with respect to the image sensor 20 to considerably improve (reduce) the warpage by using an interaction effect of the three factors.

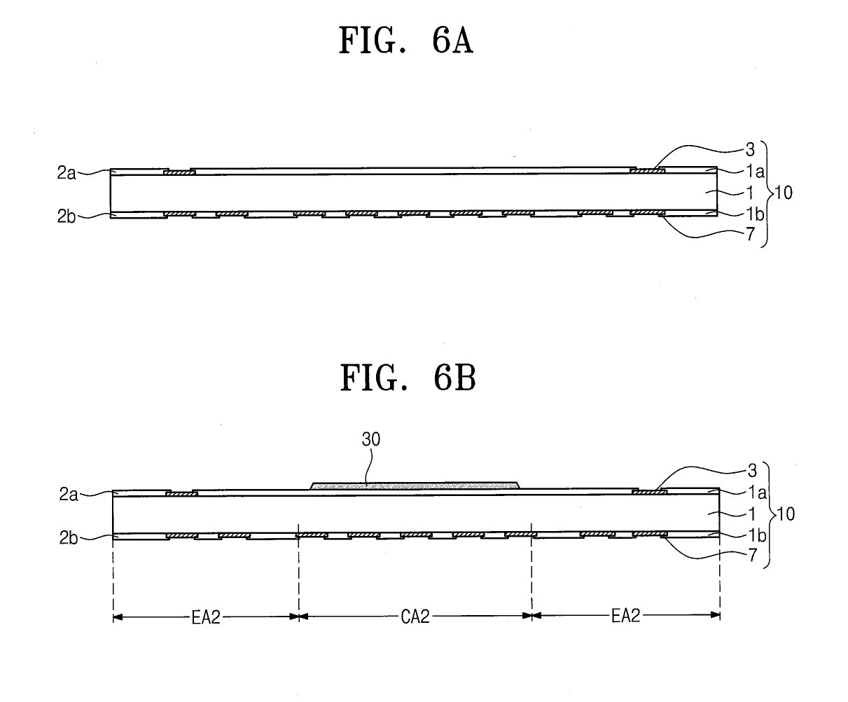

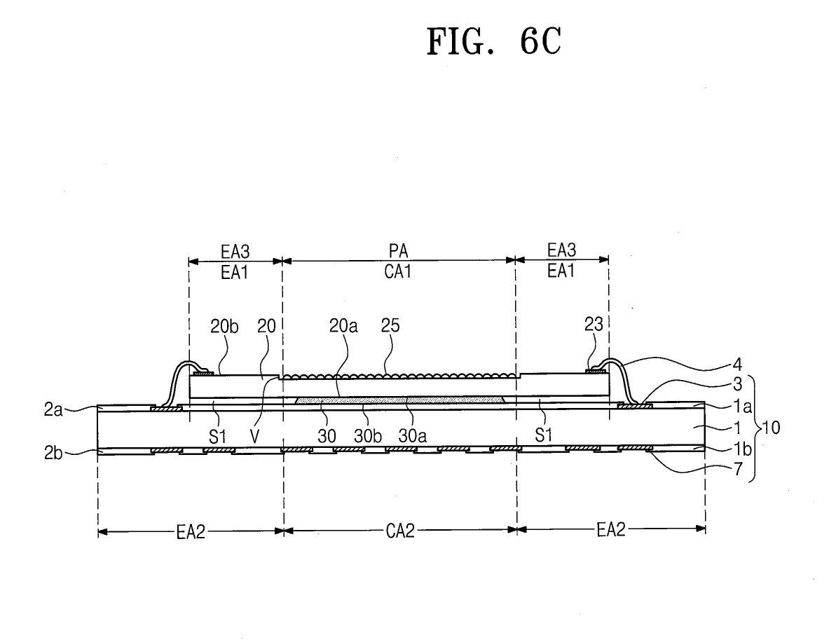

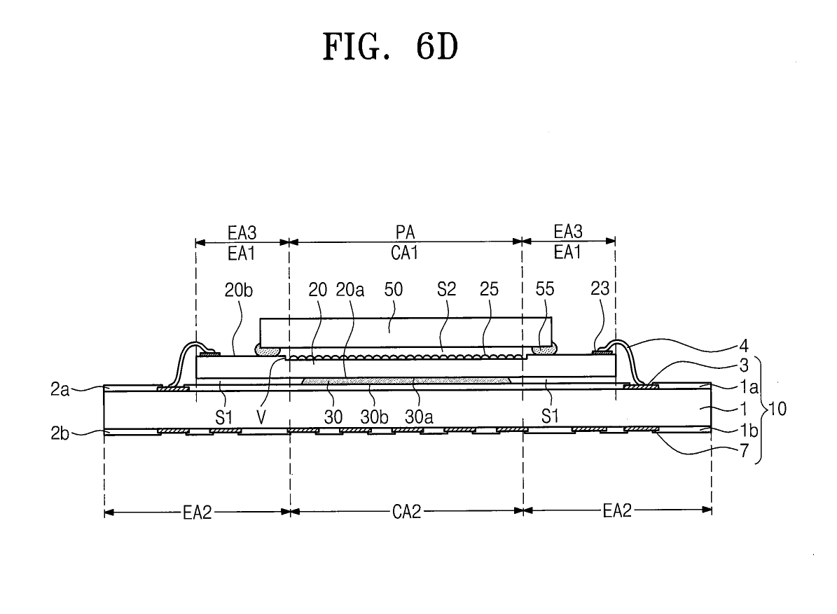

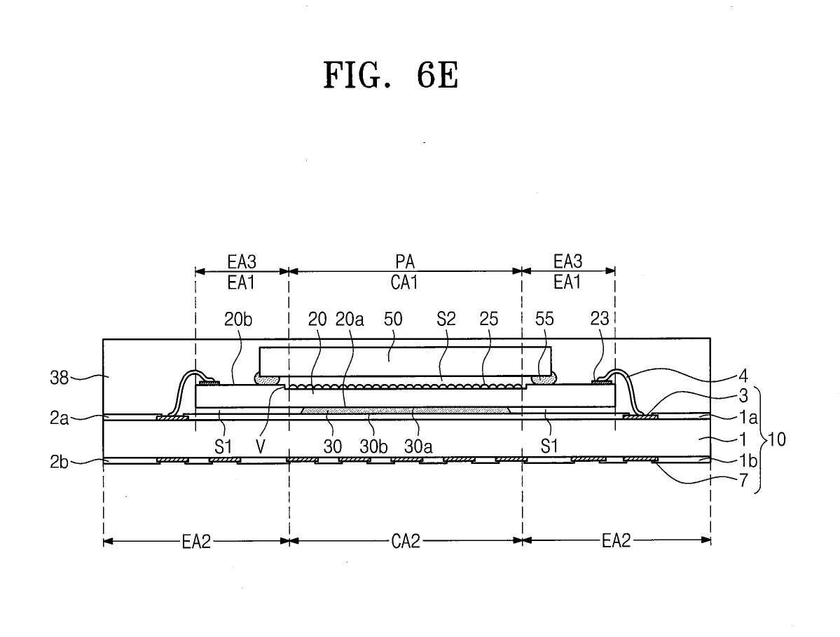

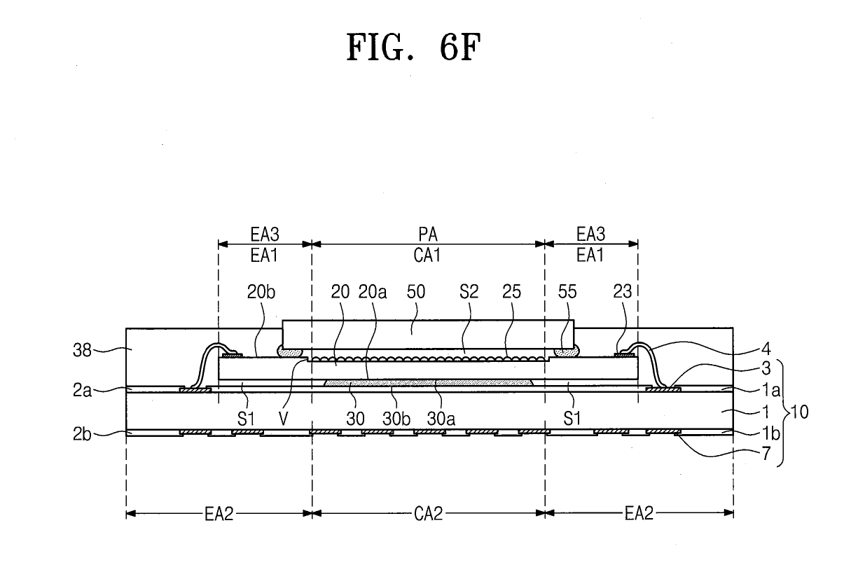

FIGS. 6A to 6F are views sequentially illustrating processes of manufacturing a semiconductor package 200 according to Embodiment 2 of the inventive concept.

Processes of manufacturing a semiconductor package 200 according to Embodiment 2 of the inventive concept will be described with reference to FIGS. 6A to 6F. However, it is noted that, in the interest of brevity, the description will be made primarily based on elements different from those constituting the semiconductor package 100 according to Embodiment 1 of the inventive concept, and other details are the same as those described above with reference to FIGS. 4A to 4E.

Referring to FIG. 6A, firstly, a substrate 10 may be prepared. Details regarding the preparing of the substrate 10 are the same as those described above with reference to FIG. 4A.

Referring to FIG. 6B, an adhesion layer 30 may be formed on the substrate 10. Details regarding the forming of the adhesion layer 30 are the same as those described above with reference to FIG. 4B.

Referring to FIG. 6C, the image sensor chip 20 may be attached on the substrate 10 by using the adhesion layer 30. A recess or recessed region V may be formed on the pixel portion PA of the image sensor chip 20, and a micro lens array 25 may be disposed inside the recess region V. Other details regarding the attaching of the image sensor chip 20 by using the adhesion layer 30 are the same as those described above with reference to FIG. 4C.

Referring to FIG. 6D, a transparent substrate 50 may be formed on the image sensor chip 20. In more detail, after a second adhesion film 55 is formed on a third edge portion EA3 of the image sensor chip 20, the transparent substrate 50 may be disposed on the image sensor chip 20. Thus, a second cavity S2 being an empty space may be defined between the transparent substrate 50 and the pixel portion PA. Subsequently, a process of curing the second adhesion film 55 may be performed. For this process, a process of irradiating ultraviolet rays or a heating process may be performed. Other details regarding the transparent substrate 50 are the same as those described above with reference to FIGS. 5A and 5B.

Referring to FIG. 6E, a mold film 38 may be formed on the substrate 10. In detail, an epoxy resin may be dropped and/or coated on the substrate 10, and then be cured to form the mold film 38. An upper surface of the mold film 38 may be formed above or on a level higher than that of an upper surface of the transparent substrate 50.

Referring to FIG. 6F, a polishing process such as a chemical mechanical polishing process may be performed to remove an upper portion of the mold film 38. Thus, the upper surface of the mold film 38 may be coplanar with the upper surface of the transparent substrate 50 or be below or located on a level lower than that of the upper surface of the transparent substrate 50. Other details regarding the mold film 38 are the same as those described above with reference to FIGS. 5A and 5B.

Next, referring to FIG. 5B, solder bumps 60 may be attached to the second substrate connection terminal 7.

### Application Example

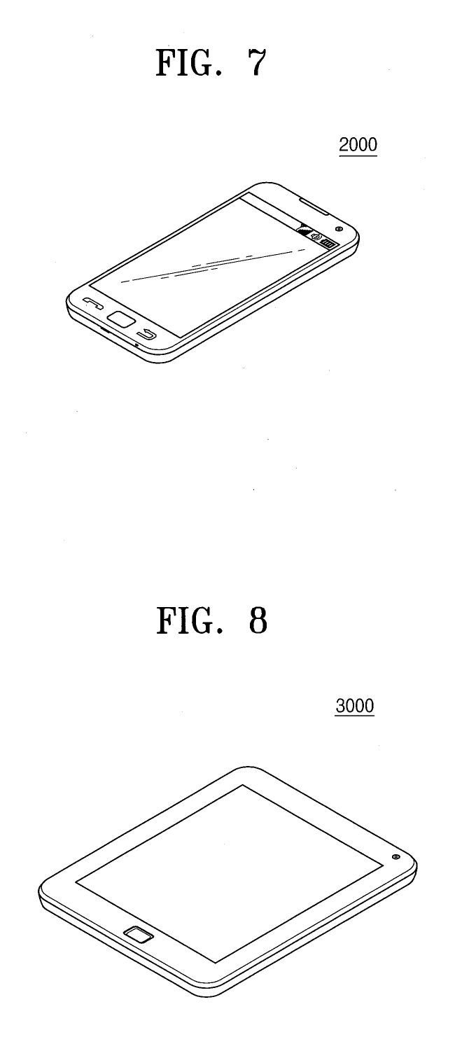

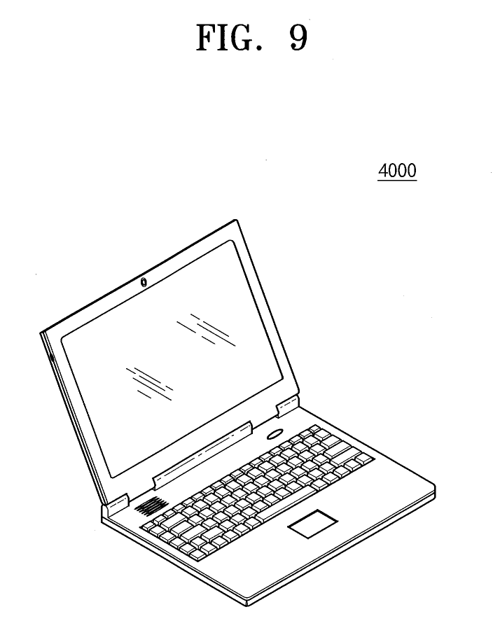

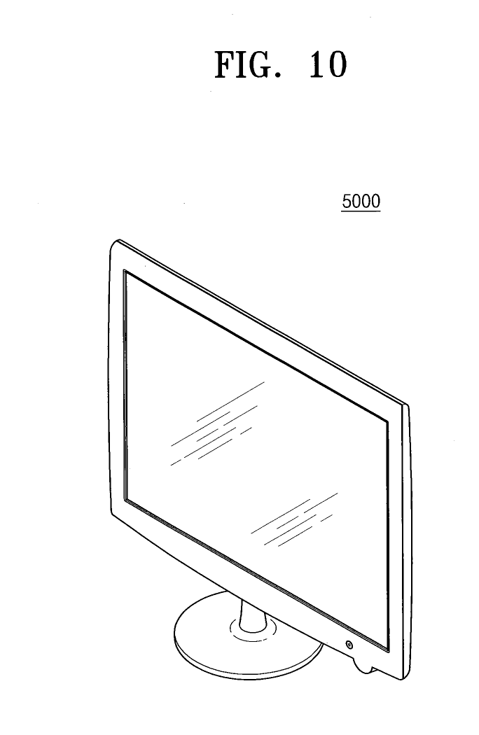

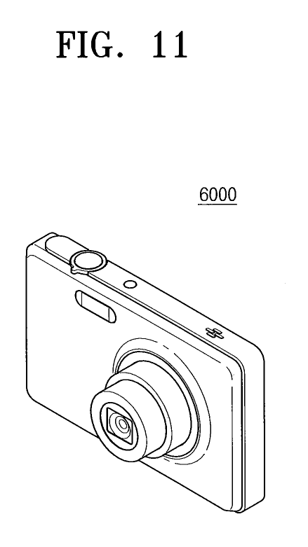

FIGS. 7 to 11 are views illustrating multimedia devices to which a semiconductor package according to embodiments of the inventive concept may be applied. Semiconductor packages 100 and 200 according to embodiments of the inventive concept may be applied to an image imaging apparatus, and the image imaging apparatus may be applied to various apparatuses equipped with an image imaging function. For example, the semiconductor packages 100 and 200 according to embodiments of the inventive concept may be applied to a mobile phone or smart phone 2000 as shown in FIG. 7, and may be applied to a tablet or smart tablet 3000 as shown in FIG. 8. Furthermore, the semiconductor packages 100 and 200 according to embodiments of the inventive concept may be applied to a notebook computer 4000 as shown in FIG. 9, and may be applied to a television or smart television 5000 as shown in FIG. 10. The semiconductor packages 100 and 200 according to embodiments of the inventive concept may be applied to a digital camera or digital camcorder 6000.

In the drawings and specification, there have been disclosed embodiments of the inventive concept and, although specific terms are employed, they are used in a generic and descriptive sense only and not for purposes of limitation, the scope of the inventive concept being set forth in the following claims.

What is claimed is:

1. A semiconductor package comprising:
a substrate;
an image sensor chip disposed on the substrate and including a first surface that faces the substrate and a second surface that is opposed to the first surface;
an adhesion layer interposed between the substrate and the image sensor chip; and
a first cavity surrounded by the first surface of the image sensor chip, an upper surface of the substrate and a side surface of the adhesion layer,
wherein the first surface of the image sensor chip comprises a first central portion and a first edge portion, and the adhesion layer comprises a first adhesion portion directly contacting the first central portion and a second adhesion portion directly contacting the upper surface of the substrate,
wherein the first adhesion portion has an area of about 5% to about 50% of an area of the first surface of the image sensor chip.

2. The semiconductor package of claim 1, wherein the substrate comprises a second central portion and a second edge portion, and wherein the second adhesion portion directly contacts the second central portion.

3. The semiconductor package of claim 1, wherein the adhesion layer has a thickness of about 1 μm to about 80 μm, and wherein the second adhesion portion has an area greater than that of the first adhesion portion.

4. The semiconductor package of claim 1, wherein the first adhesion portion is spaced apart from the first edge portion of the image sensor chip, and wherein the first adhesion portion has a circular shape on the image sensor chip first surface.

5. The semiconductor package of claim 1, wherein the adhesion layer has a modulus of about 2.7 MPa to about 4.2 MPa at a temperature of about −60° C. to about 230° C.

6. The semiconductor package of claim 1, wherein the substrate is a plastic substrate.

7. The semiconductor package of claim 6, wherein the plastic substrate is a printed circuit board (PCB).

8. The semiconductor package of claim 1, wherein the substrate has a thermal expansion coefficient of about 13 ppm/° C. or less at room temperature.

9. The semiconductor package of claim 1, wherein the image sensor has a warpage of about 10 μm or less.

10. The semiconductor package of claim 1, further comprising:
a holder having an upper surface spaced apart from the second surface of the image sensor chip; and
a transparent substrate disposed so as to be adjacent the upper surface of the holder.

11. The semiconductor package of claim 10, further comprising a second cavity surrounded by the transparent substrate, the holder and the image sensor chip.

12. The semiconductor package of claim 10, wherein the substrate, the image sensor chip, the adhesion layer, the holder and the transparent substrate are comprised of materials having different material characteristics.

13. The semiconductor package of claim 1, further comprising:
a transparent substrate on the image sensor chip; and
a mold film covering a side surface of the transparent substrate and a side surface of the image sensor chip,
wherein the first cavity is surrounded by the first surface of the image sensor chip, the upper surface of the substrate, the side surface of the adhesion layer, and the mold film.

14. A semiconductor package comprising:
a substrate;
an image sensor chip disposed on the substrate and including a first surface that faces the substrate and a second surface that is opposite the first surface; and
an adhesion layer interposed between the substrate and the image sensor chip,
wherein the adhesion layer comprises a first adhesion portion directly contacting the first surface of the image sensor chip,
wherein an area of the first adhesion portion is about 5% to about 50% of an area of the first surface, and
wherein the adhesion layer has an elastic modulus of about 2.7 MPa to about 4.2 MPa at a temperature of about −60° C. to about 230° C.

15. The semiconductor package of claim 14, wherein the substrate has a thermal expansion coefficient of about 13 ppm/° C. or less at room temperature.

16. A semiconductor package comprising:
a substrate comprising a printed circuit board (PCB), the substrate comprising first and second opposing sides;
an image sensor chip on the substrate, the image sensor chip comprising a first side that faces the substrate and a second side opposing the first side; and
an adhesion layer between the substrate and the image sensor chip;
wherein the first side of the image sensor chip comprises a first central portion and a first edge portion, and wherein the adhesion layer comprises: a first adhesion surface directly contacting the first central portion and spaced apart from the first edge portion; and a second adhesion surface directly contacting the first side of the substrate.

17. The semiconductor package of claim 16, further comprising:
a holding member on the substrate, the holding member comprising an upper surface spaced apart from the second side of the image sensor chip; and
a transparent substrate on the upper surface of the holding member.

18. The semiconductor package of claim 16, further comprising:
a transparent substrate on the image sensor chip; and
a mold film covering at least a portion of a side surface of the transparent substrate and a side surface of the image sensor chip,
wherein the first side of the image sensor chip, the first side of the substrate, the side surface of the adhesion layer, and the mold film define a first cavity.

19. The semiconductor package of claim 18, further comprising a microlens array in a recessed region defined in the second side of the image sensor chip.

20. The semiconductor package of claim 16, wherein the first adhesion surface has an area of about 5% to about 50% of an area of the first side of the image sensor chip.
